(19) United States
(12) Patent Application Publication
(10) Pub. No.: US 2016/0322308 A1
(43) Pub. Date: Nov. 3, 2016

(54) REAR SURFACE-PROTECTIVE FILM, FILM, METHOD FOR PRODUCING SEMICONDUCTOR DEVICE, AND METHOD FOR PRODUCING CHIP

(71) Applicant: NITTO DENKO CORPORATION, Osaka (JP)

(72) Inventors: Naohide TAKAMOTO, Osaka (JP); Ryuichi KIMURA, Osaka (JP)

(73) Assignee: NITTO DENKO CORPORATION, Osaka (JP)

(21) Appl. No.: 15/140,620

(22) Filed: Apr. 28, 2016

(30) Foreign Application Priority Data
Apr. 30, 2015 (JP) 2015-092983

(51) Int. Cl. H01L 23/544; H01L 23/00; H01L 23/31; H01L 21/683; H01L 21/78

(52) U.S. Cl. CPC H01L 23/544; H01L 21/6836; H01L 21/78; H01L 23/3171; H01L 24/17; H01L 2221/68327; H01L 2221/68386; H01L 2223/5442; H01L 2224/16227; H01L 2224/16245

(57) ABSTRACT

Disclosed are a rear surface-protective film making it possible to detect, after this film is bonded to a semiconductor wafer, a notch in this wafer, and to prevent the rear surface-protective film from being stuck out; and others. Disclosed are a rear surface-protective filmmaking it possible to detect, after this film is bonded to a semiconductor wafer, a notch in this wafer; and others. An aspect of the invention relates to a rear surface-protective film for being bonded to a rear surface of a semiconductor wafer. The film is smaller in outer circumstance than the semiconductor wafer, and a notch is provided in the film. Another aspect of the invention relates to a rear surface-protective film having a total light transmittance of 3% or more at a wavelength of 555 nm.

### BACKGROUND OF THE INVENTION

1. Field of the Invention

The present invention relates to a rear surface-protective film, a film, a method for producing a semiconductor device, and a method for producing a chip.

2. Description of the Related Art

In recent years, a flip chip type semiconductor device has widely been used, in which semiconductor elements such as semiconductor chips are mounted on a substrate by flip chip bonding. In the flip chip type semiconductor device, a rear surface-protective film may be provided onto the rear surface of the semiconductor elements to prevent a damage of the semiconductor elements, and others. The rear surface-protective film is usually colored to make a mark printed thereon by a laser (hereinafter, the mark will be referred to as the “laser mark”) perceptible (see, for example, Patent Document 1).

### PRIOR ART DOCUMENT

### Patent Document

Patent Document 1: Japanese Patent No. 4762959

Since the rear surface-protective film is colored, it is difficult to detect a notch in a semiconductor wafer after the rear surface-protective film is bonded to the semiconductor wafer. Moreover, by bonding the rear surface-protective film to the semiconductor wafer, the rear surface-protective film may be stuck out.

### SUMMARY OF THE INVENTION

An object of a first aspect of the present invention is to provide a rear surface-protective film and a film each making it possible to detect, after the rear surface-protective film is bonded to a semiconductor wafer, a notch in the semiconductor wafer, and to prevent the rear surface-protective film from being stuck out. Another object of the first aspect of the present invention is to provide a method for producing a semiconductor device and a method for producing a chip, these methods each making it possible to detect, after a rear surface-protective film is bonded to a semiconductor wafer, a notch in the semiconductor wafer, and to prevent the rear surface-protective film from being stuck out.

An object of a second aspect of the present invention is to provide a rear surface-protective film and a film each making it possible to detect, after the rear surface-protective film is bonded to a semiconductor wafer, a notch in the semiconductor wafer. Another object of the second aspect of the present invention is to provide a method for producing a semiconductor device and a method for producing a chip, these methods each making it possible to detect, after a rear surface-protective film is bonded to a semiconductor wafer, a notch in the semiconductor wafer.

The first aspect of the present invention relates to a rear surface-protective film for being bonded to a rear surface of a semiconductor wafer. The rear surface-protective film is smaller in outer circumstance than the semiconductor wafer, and a notch is provided in this film. The rear surface-protective film can be prevented from being stuck out by the matter that the rear surface-protective film is smaller in outer circumstance than the semiconductor wafer. The notch provided in the rear surface-protective film makes it possible to detect a notch in the semiconductor wafer after the rear surface-protective film is bonded to the semiconductor wafer.

The first aspect of the present invention also relates to a film including a separator, and the rear surface-protective film disposed on the separator. The film is preferably in a roll form.

The first aspect of the present invention also relates to a method for producing a semiconductor device, the method including a step of bonding a semiconductor wafer and the rear surface-protective film to each other. The step of bonding the semiconductor wafer and the rear surface-protective film to each other is preferably a step of bonding the semiconductor wafer and the rear surface-protective film to each other to form a stacked plate. The stacked plate includes the semiconductor wafer and the rear surface-protective film contacting a rear surface of the semiconductor wafer.

When the rear surface-protective film is disposed before the semiconductor wafer and the stacked plate is viewed in a direction perpendicular to the semiconductor wafer, the notch in the rear surface-protective film may have a contour overlapping with a part of the contour of a notch provided in the semiconductor wafer. When the rear surface-protective film is disposed before the semiconductor wafer and the stacked plate is viewed in the direction perpendicular to the semiconductor wafer, the contour of the notch provided in the semiconductor wafer may be positioned outside the contour of the notch in the rear surface-protective film in the radius direction of the semiconductor wafer.

The first aspect of the present invention also relates to a method for producing a chip, the method including a step of bonding a semiconductor wafer to the rear surface-protective film. The chip includes a semiconductor element and a protective film disposed on a rear surface of the semiconductor element.

The inventors have found out that after a rear surface-protective film and a semiconductor wafer are bonded to each other, a notch in the semiconductor wafer can be detected by heightening the total light transmittance of the rear surface-protective film at a wavelength of 555 nm. In this way, the second aspect of the present invention has been achieved.

The second aspect of the present invention relates to a rear surface-protective film for being bonded to a rear surface of a semiconductor wafer. The rear surface-protective film has a total light transmittance of 3% or more at a wavelength of 555 nm. The total light transmittance of 3% or more makes it possible to detect, after the rear surface-protective film and the semiconductor wafer are bonded to each other, a notch in the semiconductor wafer.

The second aspect of the present invention also relates to a film including a separator, and the rear surface-protective film disposed on the separator.

The second aspect of the present invention also relates to a method for producing a semiconductor device, the method including a step of bonding a semiconductor wafer and the rear surface-protective film to each other.

The second aspect of the present invention also relates to a method for producing a chip, the method including a step of bonding a semiconductor wafer and the rear surface-protective film to each other. The chip includes a semiconductor element and a protective film disposed on a rear surface of the semiconductor element.

### BRIEF DESCRIPTION OF THE DRAWINGS

FIG. 1 is a schematic plan view of a film of Embodiment 1;

FIG. 2 is a schematic sectional view of a part of the film;

FIG. 3 is a schematic plan view of a rear surface-protective film;

FIG. 4 is a schematic plan view of a semiconductor wafer;

FIG. 5 is a schematic plan view of a stacked plate;

FIG. 6 is a schematic sectional view of a process for producing a semiconductor device;

FIG. 7 is a schematic sectional view of the process for producing a semiconductor device;

FIG. 8 is a schematic sectional view of the process for producing a semiconductor device;

FIG. 9 is a schematic plan view of a stacked plate in Modified Example 1;

FIG. 10 is a schematic plan view of a rear surface-protective film in Modified Example 2;

FIG. 11 is a schematic plan view of a rear surface-protective film in Modified Example 3;

FIG. 12 is a schematic plan view of a film of Embodiment 2;

FIG. 13 is a schematic sectional view of the film;

FIG. 14 is a schematic plan view of a rear surface-protective film;

FIG. 15 is a schematic plan view of a stacked plate;

FIG. 16 is a schematic sectional view of a process for producing a semiconductor device;

FIG. 17 is a schematic sectional view of the process for producing a semiconductor device; and

FIG. 18 is a schematic sectional view of the process for producing a semiconductor device.

### DETAILED DESCRIPTION OF THE PREFERRED EMBODIMENTS

Hereinafter, the present invention will be described in detail by way of embodiments thereof. However, the invention is not limited only to these embodiments.

### Embodiment 1

### Method for Producing Semiconductor Device and Method for Producing Protected Chip 5

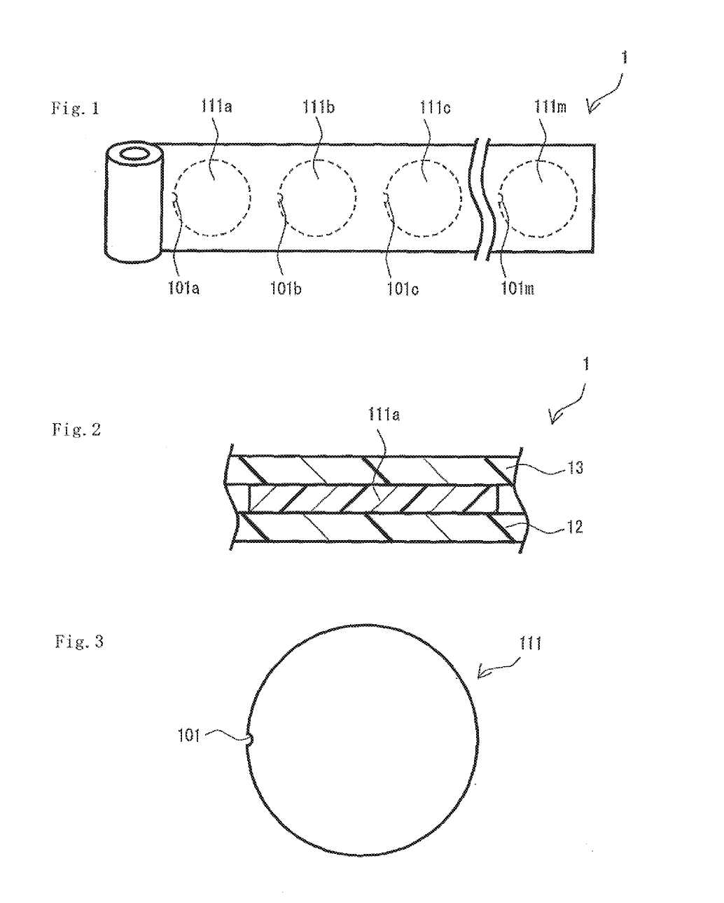

As illustrated in FIGS. 1 and 2, a film 1 is in a roll form. The film 1 includes a separator 12, and rear surface-protective films 111a, 111b, 111c . . . and 111m (hereinafter called “rear surface-protective films 111” generically) disposed on the separator 12. The film 1 further includes a separator 13 disposed on the rear surface-protective films 111. About each of the rear surface-protective films 111, both surfaces thereof can be defined as a first surface contacting the separator 12, and a second surface opposed to the first surface. The second surface contacts the separator 13.

The distance between the rear surface-protective films 111a and 111b, the distance between the rear surface-protective films 111b and 111c, . . . , and the distance between the rear surface-protective films 111l and 111m are equal to each other. About the separator 13, both ends thereof can be defined as a first end contacting a winding core, and a second end paired with the first end. Notches 101a, 101b, 101c, . . . and 101m (hereinafter called “notches 101” generically) are each positioned near the first end in a direction along which the first and second ends are linked to each other. When each of the notches is positioned near the first end, each of the rear surface-protective films 111 can easily be bonded to a semiconductor wafer 4.

As illustrated in FIG. 3, each of the rear surface-protective films 111 is in the form of a disc in which one of the notches 101 is provided.

The shape of the notch 101 provided in the rear surface-protective film 111 is equal to a part of a notch 41. The provision of the notch 101 in the rear surface-protective film 111 makes it possible to detect the notch 41 in the semiconductor wafer 4 after the rear surface-protective film 111 and the semiconductor wafer 4 are bonded to each other.

The rear surface-protective film 111 is smaller in outer circumstance than the semiconductor wafer 4. When the outer circumstance of the rear surface-protective film 111 is smaller, the rear surface-protective film 111 can be prevented from being stuck out.

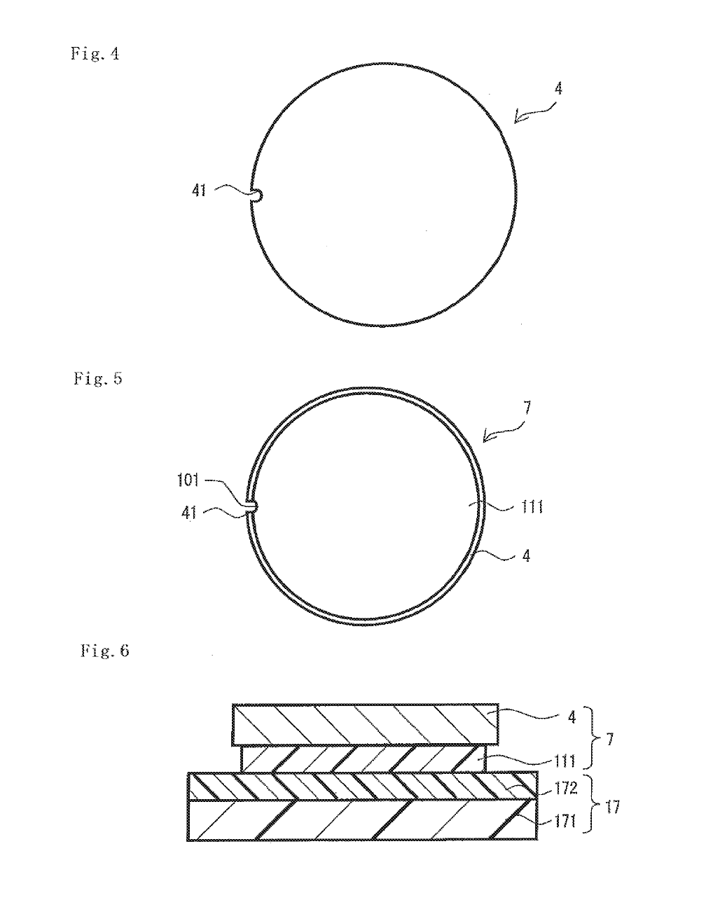

As illustrated in FIG. 4, the notch 41 is provided in the semiconductor wafer 4. About the semiconductor wafer 4, both surfaces thereof can be defined as a circuit surface, and a rear surface opposed to the circuit surface (the rear surface may also be called, for example, non-circuit surface or non-electrode formed surface). The semiconductor wafer 4 is preferably a silicon wafer.

As illustrated in FIG. 5, a stacked plate 7 is formed by bonding the rear surface-protective film 111 and the semiconductor wafer 4 to each other. Specifically, the separator 13 is peeled from the rear surface-protective film 111, and then the rear surface-protective film 111 and the semiconductor wafer 4 are bonded to each other to form the stacked plate 7.

The stacked plate 7 includes the semiconductor wafer 4, and the rear surface-protective film 111 contacting the rear surface of the semiconductor wafer 4. When the rear surface-protective film 111 is disposed before the semiconductor wafer 4 and the stacked plate 7 is viewed in a direction perpendicular to the semiconductor wafer 4, the notch 101 in the rear surface-protective film 111 has a contour overlapping with a part of the contour of the notch 41 in the semiconductor wafer 4.

By heating the stacked plate 7 as needed, the rear surface-protective film 111 is cured. The heating temperature can be appropriately set.

Through a detecting sensor for detecting the notch 41, the notch 41 in the semiconductor wafer 4 contacting the rear surface-protective film 111 is detected. This makes it possible to produce positional information on the notch 41 provided in the semiconductor wafer 4, so that a region of the rear surface-protective film 111 where a laser is to be applied can be specified. The detecting sensor is, for example, a microscope.

As needed, a print is made on the rear surface-protective film 111 of the stacked plate 7 by a laser. In the printing by the laser, a known laser marking device is usable. The laser is, for example, a gas laser, a solid laser or a liquid laser. Specifically, the gas laser is not particularly limited, and may be a known gas laser. The gas laser is preferably carbon dioxide gas laser (CO₂ laser), or an excimer laser (such as ArF laser, KrF laser, XeCl laser or XeF laser). The solid laser is not particularly limited, and may be a known solid laser. The solid laser is preferably a YAG laser (such as Nd:YAG laser), or YVO₄ laser.

Through the detecting sensor for detecting the notch 41, the notch 41 in the semiconductor wafer 4 contacting the rear surface-protective film 111 is detected. This makes it possible to produce positional information on the notch 41 provided in the semiconductor wafer 4 to match the position of the semiconductor wafer 4 with that of a dicing tape 17.

As illustrated in FIG. 6, the stacked plate 7 and the dicing tape 17 are bonded to each other. The dicing tape 17 includes a substrate 171 and a pressure-sensitive adhesive layer 172 disposed on the substrate 171. The pressure-sensitive adhesive layer 172 preferably has a property of being cured by radial rays. The radial rays are preferably ultraviolet rays.

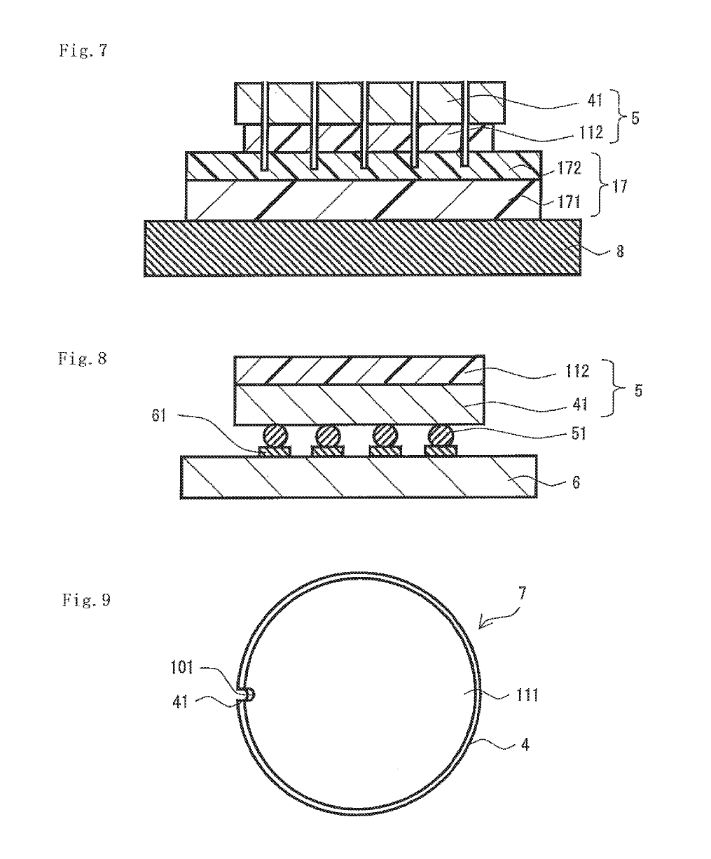

As illustrated in FIG. 7, the semiconductor wafer 4 is diced. In this way, protected chips 5 are formed. The protected chips 5 each include a semiconductor element 41 and a protective film 112 disposed on the rear surface of the semiconductor element 41. About the semiconductor element 41, both surfaces thereof can be defined as a circuit surface (the surface may also be called, for example, front surface, circuit pattern formed surface, or electrode formed surface), and a rear surface opposed to the circuit surface. The dicing is attained, for example, from the circuit surface side of the semiconductor wafer 4 in a usual way in the state that the dicing tape 17 is vacuum-adsorbed onto an adsorbing stand 8. For example, a cutting way called full cut may be adopted. A dicing machine used in the present step is not particularly limited, and may be any dicing machine known in the prior art. The semiconductor element 41 is preferably a flip chip.

Next, the protected chips 5 are peeled off from the pressure-sensitive adhesive layer 172 of the dicing tape 12. In other words, the protected chips 5 are picked up. The method for the picking-up is not particularly limited. Various method known in the prior art may be used. The method is, for example, a method of picking up the protected chips 5 with a needle, and then picking up the pricked protected chips 5 by a picking-up device.

As illustrated in FIG. 8, any one of the protected chips 5 is fixed onto an adherend 6 in a flip chip bonding manner (or in a flip chip mounting manner). Specifically, in the state that the circuit surface of the semiconductor element 41 faces the adherend 6, the protected chip 5 is fixed onto the adherend 6. For example, while bumps 51 provided on the circuit surface of the semiconductor element 41 are brought into contact with electroconductive members 61 (such as solders) for joint that cover connecting pads of the adherend 6 and then are pressed onto the electroconductive members 61, these members 61 are melted to ensure electrical conduction between the semiconductor element 41 and the adherend 6, and fix the protected chip 5 onto the adherend 6 (flip chip bonding step). At this time, gaps are made between the protected chip 5 and the adherend 6. The distance between the gaps is generally from about 30 to 300 μm. After the protected chip 5 is flip-chip-bonded (or flip-chip-connected) to the adherend 6, the facing surfaces of the protected chip 5 and the adherend 6 and the gaps are cleaned, and then a sealant (such as a sealing resin) is filled into the gaps. In this way, the present workpiece can be sealed up.

The adherend 6 may be, for example, a lead frame, or a circuit substrate (wiring circuit board), or some other substrate. The material of such a substrate is not particularly limited. The substrate may be, for example, a ceramic substrate or a plastic substrate. The plastic substrate may be, for example, an epoxy resin substrate, a bismaleimide triazine substrate, or a polyimide substrate.

The material of the bumps and the electroconductive members is not particularly limited. Examples thereof include tin-lead based, tin-silver based, tin-silver-copper based, tin-zinc based and tin-zinc-bismuth based metal materials, and other solder materials (alloys); and gold based metal materials and copper based metal materials.

When the electroconductive members 61 are melted, the temperature at the melting is usually about 260° C. (for example, 250 to 300° C.). When the rear surface-protective film 111 contains an epoxy resin, this film can resist such temperatures.

In the present step, it is preferred to clean the facing surfaces (electrode formed surfaces) of the protected chip 5 and the adherend 6, and the gaps therebetween. A cleaning liquid used for the cleaning is not particularly limited, and may be, for example, an organic cleaning liquid or an aqueous cleaning liquid.

Next, a sealing step is performed to seal the gaps between the protected chip 5 and the adherend 6 flip-chip-bonded to each other. The sealing step is performed using a sealing resin. Sealing conditions at this time are not particularly limited. Usually, by heating at 175° C. for 60 seconds to 90 seconds, the sealing resin is thermally cured. However, in the present invention, the conditions are not limited to the conditions. For example, at 165° C. to 185° C. for several minutes, the resin can be cured. This step makes it possible to thermally cure the protective film 112 completely or substantially completely. Furthermore, even when the protective film 112 is in an uncured state, this film together with the sealant can be thermally cured in this sealing step, so that it is unnecessary to add a new step of thermally curing the protective film 112.

The sealing resin is not particularly limited as far as the resin is a resin having electrically insulating property (insulating resin). The sealing resin is preferably an insulating resin having elasticity. The sealing resin is, for example, a resin composition containing an epoxy resin. The sealing resin made of this epoxy resin-containing resin composition may contain, besides the epoxy resin, for example, a thermosetting resin (such as a phenolic resin) other than any epoxy resin, or a thermoplastic resin as a resin component. The phenolic resin is usable also as a curing agent for the epoxy resin. The form of the sealing resin may be, for example, a film or tablet form.

A semiconductor device (flip-chip-bonded semiconductor device) obtained by the above-mentioned method includes the adherend 6 and the protected chip 5 fixed onto the adherend 6. A print can be made on the protective film 112 of this semiconductor device by a laser.

A semiconductor device in which semiconductor elements are mounted in a flip chip bonding manner is thinner and smaller than a semiconductor device in which semiconductor elements are mounted in a die bonding manner. For this reason, the former semiconductor device is appropriately usable for various electric instruments or electronic components, or as a component or member of these instruments or components. Specifically, an electronic instrument in which the flip-chip-bonded semiconductor device is used is, for example, the so-called “portable telephone” or “PHS”, a small-sized computer (such as the so-called “PDA” (portable data assistant), the so-called “laptop computer”, the so-called “net book (trademark)”, or the so-called “wearable computer”), a small-sized electronic instrument to which a “portable telephone” and a computer are integrated, the so-called “digital camera (trademark)”, the so-called “digital video camera”, a small-sized television, a small-sized game machine, a small-sized digital audio player, the so-called “electronic notebook”, the so-called “electronic dictionary”, the so-called electronic instrument terminal for “electronic dictionary”, a small-sized digital-type clock, or any other mobile type electronic instrument (portable electronic instrument). Of course, the electronic instrument may be, for example, an electronic instrument of a type (setup type) other than any mobile type (this instrument being, for example, the so-called “disk top computer”, a thin-type television, an electronic instrument for recording and reproduction (such as a hard disk recorder or a DVD player), a projector, or a micro machine). An electronic component in which the flip-chip-bonded semiconductor device is used, or such a component or member of an electronic instrument or electronic component is, for example, a member of the so-called “CPU”, or a member of a memorizing unit (such as the so-called “memory”, or a hard disk) that may be of various types.

As described above, the method for producing a semiconductor device includes the step of bonding the semiconductor wafer 4 and the rear surface-protective film 111 to each other. After the step of bonding the semiconductor wafer 4 and the rear surface-protective film 111 to each other, the method for producing a semiconductor device further includes the step of making a print on the rear surface-protective film 111 by a laser. The step of making the print on the rear surface-protective film 111 by the laser includes a step of detecting the notch 41 in the semiconductor wafer 4. The method for producing a semiconductor device further includes the step of bonding the dicing tape 17 to the stacked plate 7 formed through the step of bonding the semiconductor wafer 4 and the rear surface-protective film 111 to each other. The step of bonding the dicing tape 17 to the stacked plate 7 includes a step of detecting the notch 41 in the semiconductor wafer 4.

After the step of bonding the dicing tape 17 to the stacked plate 7, the method for producing a semiconductor device further includes a step of forming the protected chips 5 by dicing. The method for producing a semiconductor device further includes a step of fixing anyone of the protected chips 5 to an adherend 6. The step of fixing the protected chip 5 to the adherend 6 is preferably a step of fixing the protected chip 5 onto the adherend 6 by flip chip connection.

### (Rear Surface-Protective Film 111)

The rear surface-protective film 111 is preferably colored. When the rear surface-protective film 111 is colored, a laser mark on the rear surface-protective film 111 is easily perceptible. The rear surface-protective film 111 preferably has a deep color such as black, blue or red color. Black color is particularly preferred.

The deep color means a dark color having L* that is defined in the L*a*b* color system of basically 60 or less (0 to 60), preferably 50 or less (0 to 50) and more preferably 40 or less (0 to 40).

The black color means a blackish color having L* that is defined in the L*a*b* color system of basically 35 or less (0 to 35), preferably 30 or less (0 to 30) and more preferably 25 or less (0 to 25). In the black color, each of a* and b* that is defined in the L*a*b* color system can be appropriately selected according to the value of L*. For example, both of a* and b* are preferably −10 to 10, more preferably −5 to 5, and especially preferably −3 to 3 (above all, 0 or almost 0).

L*, a*, and b* that are defined in the L*a*b* color system can be obtained by measurement using a colorimeter (tradename: CR-200 manufactured by Konica Minolta Holdings, Inc.). The L*a*b* color system is a color space that is endorsed by Commission Internationale de I'Eclairage (CIE) in 1976, and means a color space that is called a CIE1976 (L*a*b*) color system. The L*a*b* color system is provided in JIS Z 8729 in the Japanese Industrial Standards.

The rear surface-protective film 111 is usually in an uncured state. The uncured state also includes a semi-cured state. The rear surface-protective film 111 is preferably in a semi-cured state.

When the rear surface-protective film 111 is allowed to stand still in an atmosphere of 85° C. and 85% RH for 168 hours, the moisture absorption coefficient thereof is preferably 1% by weight or less, more preferably 0.8% by weight or less. When the coefficient is 1% by weight or less, this film can be improved in laser markability. The moisture absorption coefficient is controllable by the content of an inorganic filler in the film, and others.

A method for measuring the moisture absorption coefficient of the rear surface-protective film 111 is as follows: the rear surface-protective film 111 is allowed to stand still in a thermostat of 85° C. and 85% RH for 168 hours; and the moisture absorption coefficient is gained from the film weight loss before and after the standing-still.

By curing the rear surface-protective film 111, a cured product is obtained, and the moisture absorption coefficient of this cured product is preferably 1% by weight or less, more preferably 0.8% by weight or less when this product is allowed to stand still in an atmosphere of 85° C. and 85% RH for 168 hours. When the moisture absorption coefficient is 1% by weight or less, the rear surface-protective film 111 can be improved in laser markability. The moisture absorption coefficient is controllable by the content of the inorganic filler in the film, and others.

A method for measuring the moisture absorption coefficient of the cured product is as follows: the cured product is allowed to stand still in a thermostat of 85° C. and 85% RH for 168 hours; and the moisture absorption coefficient is gained from the product weight loss before and after the standing-still.

The fraction of a gel in the rear surface-protective film 111 is preferably 50% or more, more preferably 70% or more, even more preferably 90% or more, this gel being obtained by subjecting the film 11 to extraction with ethanol. When the gel fraction is 50% or more, the rear surface-protective film 111 can be prevented from sticking onto a tool or some other in a semiconductor producing process.

The gel fraction in the rear surface-protective film 111 is controllable by the kind of a resin component, the content thereof, the kind of a crosslinking agent or the content thereof in the film, the heating temperature, the heating period, and others.

The tensile storage elastic modulus of the rear surface-protective film 111 at 23° C. is preferably 0.5 GPa or more, more preferably 0.75 GPa or more, even more preferably 1 GPa or more when the film is in an uncured state. When the tensile storage elastic modulus is 1 GPa or more, the rear surface-protective film 111 can be prevented from adhering onto a carrier tape. The upper limit of the tensile storage elastic modulus at 23° C. is, for example, 50 GPa. The tensile storage elastic modulus at 23° C. is controllable by the kind of the resin component, the content thereof, the kind of the filler or the content thereof in the film, and others.

The rear surface-protective film 111 may be electroconductive or non-electroconductive.

The adhering strength (at 23° C., a peeling angle of 180° and a peeling rate of 300 mm/minute) of the rear surface-protective film 111 to a semiconductor wafer 4 is preferably 1 N/10 mm width or more, more preferably 2 N/10 mm width or more, even more preferably 4 N/10 mm width or more. In the meantime, this adhering strength is preferably 10 N/10 mm width or less. When the adhering strength is 1 N/10 mm width or more, the rear surface-protective film 111 can adhere to a semiconductor wafer 4 or a semiconductor element with excellent adhesiveness so that this film 111 can also be prevented from undergoing a partial peeling-up and other inconveniences. When the semiconductor wafer 4 is diced, its chips can also be prevented from being scattered. The adhering strength of the rear surface-protective film 111 to a semiconductor wafer 4 is a value measured, for example, as follows: a pressure-sensitive adhesive tape (trade name: “BT315”, manufactured by Nitto Denko Corporation) is bonded to one surface of the rear surface-protective film 111 to reinforce the rear surface. Thereafter, a semiconductor wafer 4 having a thickness of 0.6 mm is bonded to the front surface of the rear surface-reinforced rear surface-protective film 111, which has a length of 150 mm and a width of 10 mm, by a thermal laminating method at 50° C. in which a roller of 2 kg weight is moved forward and backward one time onto the film. Thereafter, the resultant is allowed to stand still on a hot plate (50° C.) for 2 minutes, and then to stand still at room temperature (at about 23° C.) for 20 minutes. After the standing-still, a peeling tester (trade name: “AUTOGRAPH AGS-J”, manufactured by Shimadzu Corporation) is used to peel off the rear surface-reinforced rear surface-protective film 111 at a temperature of 23° C., a peeling angle of 180° and a tensile rate of 300 mm/minute. The adhering strength of the rear surface-protective film 111 to the semiconductor wafer 4 is a value (unit: N/10 mm width) measured for the peel of the rear surface-protective film 111 and the semiconductor wafer 4 from each other at the interface therebetween at this time.

The thickness of the rear surface-protective film 111 is preferably 2 μm or more, more preferably 4 μm or more, even more preferably 6 μm or more, in particular preferably 10 μm or more. In the meantime, the thickness of the rear surface-protective film 111 is preferably 200 μm or less, more preferably 160 μm or less, even more preferably 100 μm or less, even more preferably 80 μm or less, in particular preferably 50 μm or less.

The rear surface-protective film 111 preferably contains a colorant. The colorant may be, for example, a dye or a pigment, and is in particular preferably a dye.

The dye is preferably a deep color dye. Examples of the deep color dye may include black dyes, blue dyes, and red dyes. Black dyes are particularly preferred. Such colorants may be used singly or in any combination of two or more thereof.

The content of the colorant in the rear surface-protective film 111 is preferably 0.5% by weight or more, more preferably 1% by weight or more, even more preferably 2% by weight or more. The content of the colorant in the rear surface-protective film 111 is preferably 10% by weight or less, more preferably 8% by weight or less, even more preferably 5% by weight or less.

The rear surface-protective film 111 preferably contains a thermoplastic resin.

Examples of the thermoplastic resin include a natural rubber, a butyl rubber, an isoprene rubber, a chloroprene rubber, an ethylene-vinyl acetate copolymer, an ethylene-acrylate copolymer, an ethylene-acrylic ester copolymer, a polybutadiene resin, a polycarbonate resin, a thermoplastic polyimide resin, polyamide resins such as 6-nylon and 6,6-nylon, a phenoxy resin, an acrylic resin, saturated polyester resins such as PET (polyethylene terephthalate) and PBT (polybutylene terephthalate), a polyamideimide resin, and a fluororesin. The thermoplastic resins can be used alone or two types or more can be used together. Among these thermoplastic resins, an acrylic resin and a phenoxy resin are preferable.

The acrylic resin is not especially limited, and examples thereof include a polymer having one type or two types or more of acrylates or methacrylates having a linear or branched alkyl group having 30 or less carbon atoms (preferably 4 to 18 carbon atoms, further preferably 6 to 10 carbon atoms, and especially preferably 8 or 9 carbon atoms) as a component. That is, the acrylic resin of the present invention has a broad meaning and also includes a methacrylic resin. Examples of the alkyl group include a methyl group, an ethyl group, a propyl group, an isopropyl group, an n-butyl group, a t-butyl group, an isobutyl group, a pentyl group, an isopentyl group, a hexyl group, a heptyl group, a 2-ethylhexyl group, an octyl group, an isooctyl group, a nonyl group, an isononyl group, a decyl group, an isodecyl group, an undecyl group, a dodecyl group (a lauryl group), a tridecyl group, a tetradecyl group, a stearyl group, and an octadecyl group.

Other monomers that can form the above-described acrylic resin (monomers other than an alkylester of acrylic acid or methacrylic acid having an alkyl group having 30 or less carbon atoms) are not especially limited. Examples thereof include carboxyl-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxymethylcyclohexyl) methylacrylate; monomers which contain a sulfonic acid group, such as styrenesulfonic acid, allylsulfonic acid, 2-(meth)acrylamide-2-methylpropanesulfonic acid, (meth)acrylamidepropane sulfonic acid, sulfopropyl (meth)acrylate, and (meth)acryloyloxynaphthalenesulfonic acid; and monomers which contain a phosphoric acid group, such as 2-hydroxyethylacryloyl phosphate. (Meth)acrylate refers to an acrylate and/or a methacrylate, and every “(meth)” in the present invention has the same meaning.

The content of the thermoplastic resin in the rear surface-protective film 111 is preferably 10% by weight or more, more preferably 30% by weight or more. The content of the thermoplastic resin in the rear surface-protective film 111 is preferably 90% by weight or less, more preferably 70% by weight or less.

The rear surface-protective film 111 may contain a thermosetting resin.

Examples of the thermosetting resin include an epoxy resin, a phenolic resin, an amino resin, an unsaturated polyester resin, a polyurethane resin, a silicone resin, and a thermosetting polyimide resin. The thermosetting resins can be used alone or two types or more can be used together. An epoxy resin having a small amount of ionic impurities that erode the semiconductor element is especially suitable as the thermosetting resin. Further, a phenolic resin can be suitably used as a curing agent for the epoxy resin.

The epoxy resin is not especially limited, and examples thereof include bifunctional epoxy resins and polyfunctional epoxy resins such as a bisphenol A type epoxy resin, a bisphenol F type epoxy resin, a bisphenol S type epoxy resin, a brominated bisphenol A type epoxy resin, a hydrogenated bisphenol A type epoxy resin, a bisphenol AF type epoxy resin, a bisphenyl type epoxy resin, a naphthalene type epoxy resin, a fluorene type epoxy resin, a phenol novolak type epoxy resin, an ortho-cresol novolak type epoxy resin, a trishydroxyphenylmethane type epoxy resin, and a tetraphenylolethane type epoxy resin, a hydantoin type epoxy resin, a trisglycidylisocyanurate type epoxy resin, and a glycidylamine type epoxy resin.

Out of these examples, particularly preferred are novolak type epoxy resin, biphenyl type epoxy resin, trishydroxyphenylmethane type epoxy resin, and tetraphenylolethane type epoxy resin. This is because these epoxy resins are rich in reactivity with phenolic resin as the curing agent, and are excellent in heat resistance and the like.

The phenolic resin acts as a curing agent for the epoxy resin, and examples thereof include novolak type phenolic resins such as a phenol novolak resin, a phenol aralkyl resin, a cresol novolak resin, a tert-butylphenol novolak resin, and a nonylphenol novolak resin, a resol type phenolic resin, and polyoxystyrenes such as polyparaoxystyrene. The phenolic resins can be used alone or two types or more can be used together. Among these phenolic resins, a phenol novolak resin and a phenol aralkyl resin are especially preferable because connection reliability in a semiconductor device can be improved.

The phenolic resin is suitably compounded in the epoxy resin so that a hydroxyl group in the phenolic resin to 1 equivalent of an epoxy group in the epoxy resin component becomes 0.5 to 2.0 equivalents. The ratio is more preferably 0.8 to 1.2 equivalents.

The content of the thermosetting resin in the rear surface-protective film 111 is preferably 2% by weight or more, more preferably 5% by weight or more. The content of the thermosetting resin in the rear surface-protective film 111 is preferably 40% by weight or less, more preferably 20% by weight or less.

The rear surface-protective film 111 may contain a thermosetting promoting catalyst for the epoxy resin and the phenolic resin. The thermosetting promoting catalyst is not particularly limited, and may be appropriately selected from known thermosetting promoting catalysts. The thermosetting promoting catalysts may be used singly or in any combination of two or more thereof. The thermosetting promoting catalysts may be, for example, amine type, phosphorus-containing type, imidazole type, boron-containing type, and phosphorus-boron-containing type thermosetting promoting catalysts.

In order to crosslink the rear surface-protective film 111 to some degree in advance, it is preferred in the production of the rear surface-protective film 111 to add the following as a crosslinking agent to the rear surface-protective film 11: a polyfunctional compound reactive with, for example, a functional group of a molecular chain terminal of a polymer. This makes it possible to improve the film 11 in adhesive property at high temperature and heat resistance.

The crosslinking agent is not especially limited, and a known crosslinking agent can be used. Specific examples thereof include an isocyanate crosslinking agent, an epoxy crosslinking agent, a melamine crosslinking agent, a peroxide crosslinking agent, a urea crosslinking agent, a metal alkoxide crosslinking agent, a metal chelate crosslinking agent, a metal salt crosslinking agent, a carbodiimide crosslinking agent, an oxazoline crosslinking agent, an aziridine crosslinking agent, and an amine crosslinking agent. An isocyanate crosslinking agent and an epoxy crosslinking agent are preferable. The crosslinking agents can be used alone or two type or more can be used together.

Examples of the isocyanate crosslinking agent include lower aliphatic polyisocyanates such as 1,2-ethylene diisocyanate, 1,4-butylene isocyanate, and 1,6-hexamethylene diisocyanate; alicyclic polyisocyanates such as cyclopentylene diisocyanate, cyclohexylene diisocyanate, isophorone diisocyanate, hydrogenated tolylene diisocyanate, and hydrogenated xylene diisocyanate; and aromatic polyisocyanates such as 2,4-tolylene diisocyanate, 2,6-tolylene diisocyanate, 4,4′-diphenylmethanediisocyanate, and xylylene diisiocyanate. A trimethylolpropane/tolylene diisocyanate trimer adduct (tradename: Coronate L manufactured by Nippon Polyurethane Industry Co., Ltd.) and a trimethylolpropane/hexamethylene diisocyanate trimer adduct (tradename: Coronate HL manufactured by Nippon Polyurethane Industry Co., Ltd.) can also be used. Examples of the epoxy crosslinking agent include N,N,N′,N′-tetraglycidyl-m-xylenediamine, diglycidylaniline, 1,3-bis(N,N-glycidylaminomethyl)cyclohexane, 1,6-hexanediol diglycidylether, neopentylglycol diglycidylether, ethyleneglycol diglycidylether, propyleneglycol diglycidylether, polyethyleneglycol diglycidylether, polypropyleneglycol diglycidylether, sorbitol polyglycidylether, glycerol polyglycidylether, pentaerythritol polyglycidylether, polyglyserol polyglycidylether, sorbitan polyglycidylether, trimethylolpropane polyglycidylether, diglycidyl adipate, diglycidyl o-phthalate, triglycidyl-tris(2-hydroxyethyl)isocyanurate, resorcin diglycidylether, bisphenol-s-diglycidyl ether, and an epoxy resin having two or more epoxy groups in the molecule.

In the present invention, it is possible to perform a crosslinking treatment by irradiation with an electron beam, an ultraviolet ray, or the like in place of using the crosslinking agent or together with a crosslinking agent.

The rear surface-protective film 111 may contain a filler. When the rear surface-protective film 111 contains the filler, the film 11 can be adjusted in elastic modulus and others.

The filler may be an inorganic filler or an organic filler, and is preferably an inorganic filler. The inorganic filler may be powder of an inorganic substance that may be of various type. Examples of the substance include ceramics such as silica, clay, plaster, calcium carbonate, barium sulfate, alumina, beryllium oxide, silicon carbide and silicon nitride; metals such as aluminum, copper, silver, gold, nickel, chromium, lead, tin, zinc, palladium and solder, and any alloy composed of two or more of these metals; and carbon. Such fillers may be used singly or in any combination of two or more thereof. The filler is preferably silica, in particular preferably fused silica. The average particle diameter of the inorganic filler ranges preferably from 0.1 μm to 80 μm. The average particle diameter of the inorganic filler is measurable, using, for example, a laser diffraction type particle size distribution measuring instrument.

The content of the filler in the rear surface-protective film 111 is preferably 10% by weight or more, more preferably 20% by weight or more. The content of the filler in the rear surface-protective film 111 is preferably 70% by weight or less, more preferably 50% by weight or less.

The rear surface-protective film 111 may appropriately contain any other additive. Examples of the other additive include a flame retardant, a silane coupling agent, an ion trapping agent, an extender, an anti-aging agent, an antioxidant, and a surfactant.

Examples of the flame retardant include antimony trioxide, antimony pentoxide, and a brominated epoxy resin. These can be used alone or two types or more can be used together. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These compounds can be used alone or two types or more can be used together. Examples of the ion trap agent include hydrotalcites and bismuth hydroxide. These can be used alone or two types or more can be used together.

The rear surface-protective film 111 can be yielded by, for example, a method of mixing a thermosetting resin, a thermoplastic resin, a solvent and others with one another to prepare a mixed liquid, applying the mixed liquid onto a peeling paper piece, and drying the resultant workpiece.

### (Separator 12)

The separator 12 may be, for example, a polyethylene terephthalate (PET) film. The separator 12 is preferably a separator subjected to release treatment. The thickness of the separator 12 may be appropriately set.

### (Separator 13)

The separator 13 may be, for example, a polyethylene terephthalate (PET) film. The separator 13 is preferably a separator subjected to release treatment. The thickness of the separator 13 may be appropriately set.

### Modified Example 1

As illustrated in FIG. 9, when a rear surface-protective film 111 is disposed before a semiconductor wafer 4 and a stacked plate 7 is viewed in a direction perpendicular to the semiconductor wafer 4, the stacked plate 7 has a specified shape. Specifically, the contour of a notch 41 in the semiconductor 4 is positioned outside the contour of a notch 101 in the rear surface-protective film 111 in the radius direction of the semiconductor wafer 4.

### Modified Example 2

As illustrated in FIG. 10, a notch 101 is in a V-shaped form.

### Modified Example 3

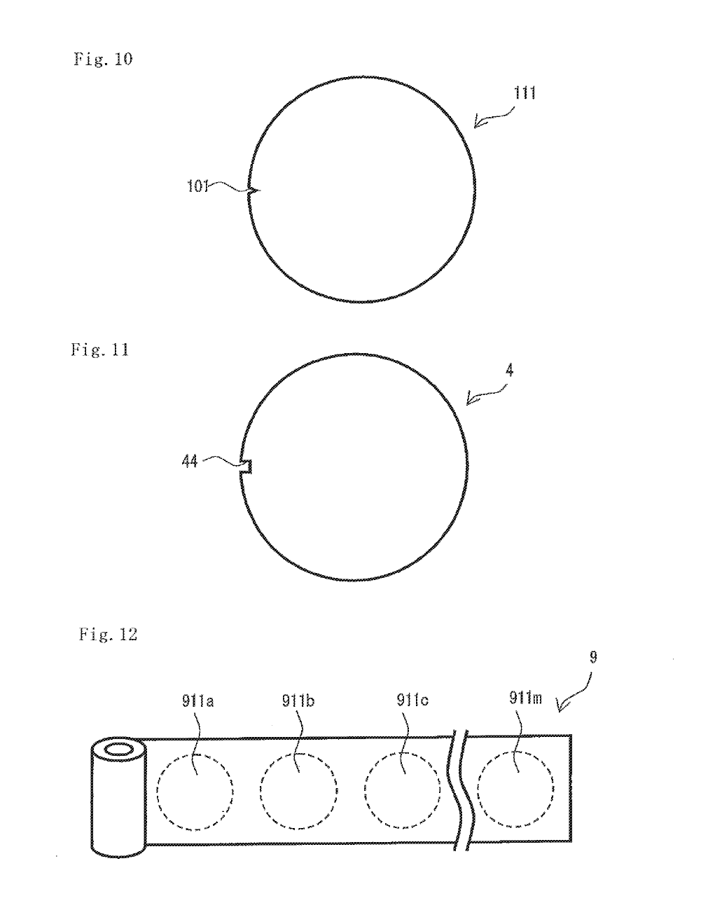

As illustrated in FIG. 11, a notch 101 is in a rectangular form.

### Modified Example 4

The notch 101 is mathematically similar to the notch 41. The notch 101 is larger than the notch 41.

### Modified Example 5

The notch 101 is equal in shape to the notch 41.

### Modified Example 6

The rear surface-protective films 111 each have a multilayered form including a first layer and a second layer disposed on the first layer.

### Other Modified Examples

Two or more of Modified Examples 1 to 6 and others may be arbitrarily combined with each other.

### Embodiment 2

Hereinafter, Embodiment 2 will be described. Any description about the same members as described about Embodiment 1 is basically omitted.

### (Method for Producing Semiconductor Device)

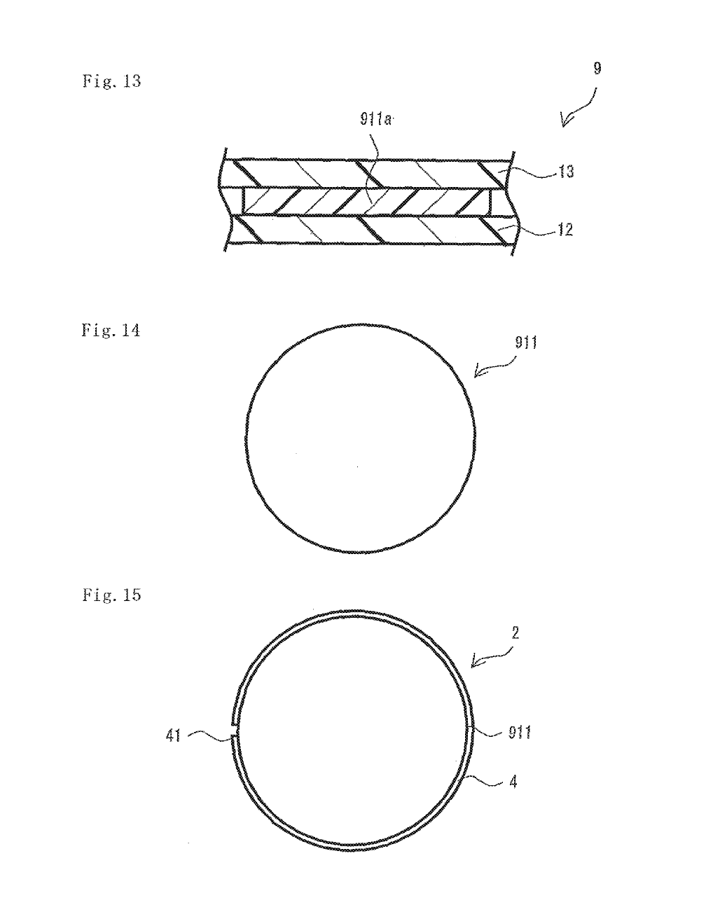

As illustrated in FIGS. 12 and 13, a film 9 is in a roll form. The film 9 includes a separator 12, and rear surface-protective films 911a, 911b, 911c . . . and 911m (hereinafter named “rear surface-protective films 911” generically) disposed on the separator 12. The film 9 further includes a separator 13 disposed on the rear surface-protective films 911. About each of the rear surface-protective films 911, both surfaces thereof can be defined as a first surface contacting the separator 12, and a second surface opposed to the first surface. The second surface contacts the separator 13.

The distance between the rear surface-protective films 911a and 911b, the distance between the rear surface-protective films 911b and 911c, . . . , and the distance between the rear surface-protective films 9111 and 911m are equal to each other.

As illustrated in FIG. 14, each of the rear surface-protective films 911 is in a disc form.

The rear surface-protective film 911 is smaller in outer circumstance than a semiconductor wafer 4. When the outer circumstance of the rear surface-protective film 911 is smaller, the rear surface-protective film 911 can be prevented from being stuck out.

As illustrated in FIG. 15, a stacked plate 2 is formed by bonding the rear surface-protective film 911 and the semiconductor wafer 4 to each other. Specifically, the separator 13 is peeled off from the rear surface-protective film 911, and the rear surface-protective film 911 and the semiconductor wafer 4 are bonded to each other to form the stacked plate 2.

The stacked plate 2 includes the semiconductor wafer 4, and the rear surface-protective film 911 contacting the rear surface of the semiconductor wafer 4.

By heating the stacked plate 2 as needed, the rear surface-protective film 911 is cured. The heating temperature may be appropriately set.

Through a detecting sensor for detecting a notch 41, the notch 41 in the semiconductor wafer 4 contacting the rear surface-protective film 911 is detected. This makes it possible to produce positional information on the notch 41 provided in the semiconductor wafer 4, so that a region of the rear surface-protective film 911 where a laser is to be applied can be specified. Examples of the detecting sensor include microscopes, transmission type sensors, and reflection type sensors.

As needed, a print is made on the rear surface-protective film 911 of the stacked plate 2 by a laser.

Through a detecting sensor for detecting a notch 41, the notch 41 in the semiconductor wafer 4 contacting the rear surface-protective film 911 is detected. This makes it possible to produce positional information on the notch 41 provided in the semiconductor wafer 4 to match the position of the semiconductor wafer 4 with that of a dicing tape 17.

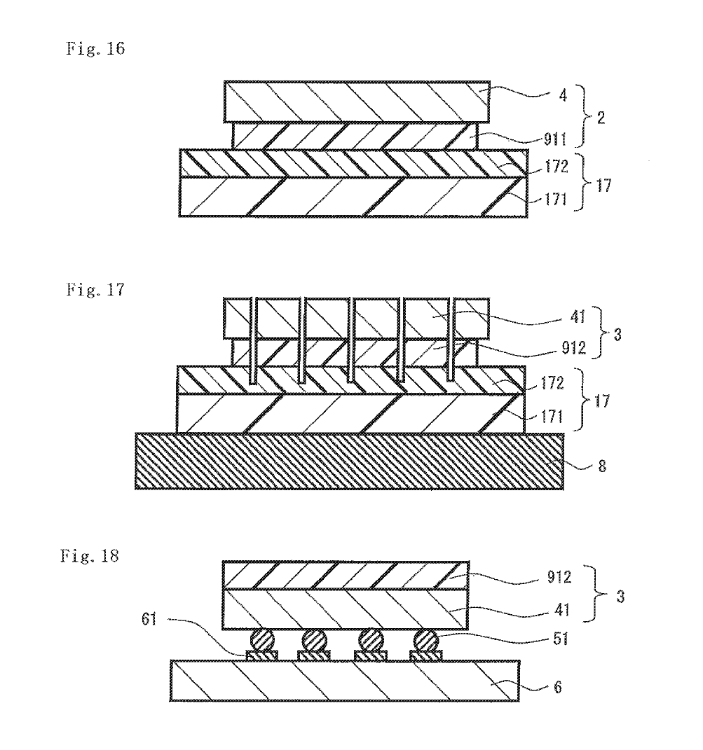

As illustrated in FIG. 16, the stacked plate 2 and the dicing tape 17 are bonded to each other.

As illustrated in FIG. 17, the semiconductor wafer 4 is diced. In this way, protected chips 3 are formed. The protected chips 3 each include a semiconductor element 41 and a protective film 912 disposed on the rear surface of the semiconductor element 41. About the semiconductor element 41, both surfaces thereof can be defined as a circuit surface (the surface may also be called, for example, front surface, circuit pattern formed surface, or electrode formed surface), and a rear surface opposed to the circuit surface. The dicing is attained, for example, from the circuit surface side of the semiconductor wafer 4 in a usual way in the state that the dicing tape 17 is vacuum-adsorbed onto an adsorbing stand 8. For example, a cutting way called full cut may be adopted. A dicing machine used in the present step is not particularly limited, and may be any dicing machine known in the prior art.

Next, the protected chips 3 are peeled off from the pressure-sensitive adhesive layer 172 of the dicing tape 17. In other words, the protected chips 3 are picked up.

As illustrated in FIG. 18, any one of the protected chips 3 is fixed onto an adherend 6 in a flip chip bonding manner (or in a flip chip mounting manner). Specifically, in the state that the circuit surface of the semiconductor element 41 faces the adherend 6, the protected chip 3 is fixed onto the adherend 6. For example, while bumps 51 provided on the circuit surface of the semiconductor element 41 are brought into contact with electroconductive members 61 (such as solders) for joint that cover connecting pads of the adherend 6 and then are pressed onto the electroconductive members 61, these members 61 are melted to ensure electrical conduction between the semiconductor element 41 and the adherend 6, and fix the protected chip 3 onto the adherend 6 (flip chip bonding step). At this time, gaps are made between the protected chip 3 and the adherend 6. The distance between the gaps is generally from about 30 to 300 μm. After the protected chip 3 is flip-chip-bonded (or flip-chip-connected) to the adherend 6, the facing surfaces of the protected chip 3 and the adherend 6 and the gaps are cleaned, and then a sealant (such as a sealing resin) is filled into the gaps. In this way, the present workpiece can be sealed up.

In the present step, it is preferred to clean the facing surfaces (electrode formed surfaces) of the protected chip 3 and the adherend 6, and the gaps therebetween.

Next, a sealing step is performed to seal the gaps between the protected chip 3 and the adherend 6 flip-chip-bonded to each other. The sealing step is performed using a sealing resin. Sealing conditions at this time are not particularly limited. Usually, by heating at 175° C. for 60 seconds to 90 seconds, the sealing resin is thermally cured. However, in the present invention, the conditions are not limited to the conditions. For example, at 165° C. to 185° C. for several minutes, the resin can be cured. This step makes it possible to thermally cure the rear surface-protective films 911 completely or substantially completely. Furthermore, even when the rear surface-protective films 911 is in an uncured state, this film together with the sealant can be thermally cured in this sealing step, so that it is unnecessary to add a new step of thermally curing the rear surface-protective films 911.

A semiconductor device (flip-chip-bonded semiconductor device) obtained by the above-mentioned method includes the adherend 6 and the protected chip 3 fixed onto the adherend 6. A print can be made on the protective film 912 of this semiconductor device by a laser.

As described above, the method for producing a semiconductor device includes the step of bonding the semiconductor wafer 4 and the rear surface-protective film 911 to each other. After the step of bonding the semiconductor wafer 4 and the rear surface-protective film 911 to each other, the method for producing a semiconductor device further includes the step of making a print on the rear surface-protective film 911 by a laser. The step of making the print on the rear surface-protective film 911 by the laser includes a step of detecting the notch 41 in the semiconductor wafer 4. The method for producing a semiconductor device further includes the step of bonding the dicing tape 17 to the stacked plate 2 formed through the step of bonding the semiconductor wafer 4 and the rear surface-protective film 911 to each other. The step of bonding the dicing tape 17 to the stacked plate 2 includes a step of detecting the notch 41 in the semiconductor wafer 4.

After the step of bonding the dicing tape 17 to the stacked plate 2, the method for producing a semiconductor device further includes a step of forming the protected chips 3 by dicing. The method for producing a semiconductor device further includes a step of fixing any one of the protected chips 3 to an adherend 6. The step of fixing the protected chip 3 to the adherend 6 is preferably a step of fixing the protected chip 3 onto the adherend 6 by flip chip connection.

### (Rear Surface-Protective Films 911)

The total light transmittance of each of the rear surface-protective films 911 at a wavelength of 555 nm is 3% or more, preferably 5% or more, more preferably 7% or more. When the total light transmittance is 3% or more, the notch 41 in the semiconductor wafer 4 can be detected after the rear surface-protective film 911 and the semiconductor wafer 4 are bonded to each other. The upper limit of the total light transmittance of the rear surface-protective film 911 at the wavelength of 555 nm is, for example, 50%, 30% or 20%.

The total light transmittance at the wavelength of 555 nm is controllable by the thickness of the rear surface-protective film 911, the kind of a colorant, and some others. For example, the reduction of the thickness of the rear surface-protective film 911 or the use of a dye as the colorant makes it possible to heighten the total light transmittance at the wavelength of 555 nm.

The rear surface-protective film 911 is preferably colored. When the rear surface-protective film 911 is colored, a laser mark on the rear surface-protective film 911 is easily perceptible. The rear surface-protective film 911 preferably has a deep color such as black, blue or red color. Black color is particularly preferred.

The deep color means a dark color having L* that is defined in the L*a*b* color system of basically 60 or less (0 to 60), preferably 50 or less (0 to 50) and more preferably 40 or less (0 to 40).

The black color means a blackish color having L* that is defined in the L*a*b* color system of basically 35 or less (0 to 35), preferably 30 or less (0 to 30) and more preferably 25 or less (0 to 25). In the black color, each of a* and b* that is defined in the L*a*b* color system can be appropriately selected according to the value of L*. For example, both of a* and b* are preferably −10 to 10, more preferably −5 to 5, and especially preferably −3 to 3 (above all, 0 or almost 0).

L*, a*, and b* that are defined in the L*a*b* color system can be obtained by measurement using a colorimeter (tradename: CR-200 manufactured by Konica Minolta Holdings, Inc.). The L*a*b* color system is a color space that is endorsed by Commission Internationale de I'Eclairage (CIE) in 1976, and means a color space that is called a CIE1976 (L*a*b*) color system. The L*a*b* color system is provided in JIS Z 8729 in the Japanese Industrial Standards.

The rear surface-protective film 911 is usually in an uncured state. The uncured state also includes a semi-cured state. The rear surface-protective film 911 is preferably in a semi-cured state.

When the rear surface-protective film 911 is allowed to stand still in an atmosphere of 85° C. and 85% RH for 168 hours, the moisture absorption coefficient thereof is preferably 1% by weight or less, more preferably 0.8% by weight or less. When the coefficient is 1% by weight or less, this film can be improved in laser markability. The moisture absorption coefficient is controllable by the content of an inorganic filler in the film, and others.

A method for measuring the moisture absorption coefficient of the rear surface-protective film 911 is as follows: the rear surface-protective film 911 is allowed to stand still in a thermostat of 85° C. and 85% RH for 168 hours; and the moisture absorption coefficient is gained from the film weight loss before and after the standing-still.

By curing the rear surface-protective film 911, a cured product is obtained, and the moisture absorption coefficient of this cured product is preferably 1% by weight or less, more preferably 0.8% by weight or less when this product is allowed to stand still in an atmosphere of 85° C. and 85% RH for 168 hours. When the moisture absorption coefficient is 1% by weight or less, the rear surface-protective film 911 can be improved in laser markability. The moisture absorption coefficient is controllable by the content of the inorganic filler in the film, and others.

A method for measuring the moisture absorption coefficient of the cured product is as follows: the cured product is allowed to stand still in a thermostat of 85° C. and 85% RH for 168 hours; and the moisture absorption coefficient is gained from the product weight loss before and after the standing-still.

The fraction of a gel in the rear surface-protective film 911 is preferably 50% or more, more preferably 70% or more, even more preferably 90% or more, this gel being obtained by subjecting the film 11 to extraction with ethanol. When the gel fraction is 50% or more, the rear surface-protective film 911 can be prevented from sticking onto a tool or some other in a semiconductor producing process.

The gel fraction in the rear surface-protective film 911 is controllable by the kind of a resin component, the content thereof, the kind of a crosslinking agent or the content thereof in the film, the heating temperature, the heating period, and others.

The tensile storage elastic modulus of the rear surface-protective film 911 at 23° C. is preferably 0.5 GPa or more, more preferably 0.75 GPa or more, even more preferably 1 GPa or more when the film is in an uncured state. When the tensile storage elastic modulus is 1 GPa or more, the rear surface-protective film 911 can be prevented from adhering onto a carrier tape. The upper limit of the tensile storage elastic modulus at 23° C. is, for example, 50 GPa. The tensile storage elastic modulus at 23° C. is controllable by the kind of the resin component, the content thereof, the kind of the filler or the content thereof in the film, and others.

The rear surface-protective film 911 may be electroconductive or non-electroconductive.

The adhering strength (at 23° C., a peeling angle of 180° and a peeling rate of 300 mm/minute) of the rear surface-protective film 911 to a semiconductor wafer 4 is preferably 1 N/10 mm width or more, more preferably 2 N/10 mm width or more, even more preferably 4 N/10 mm width or more. In the meantime, this adhering strength is preferably 10 N/10 mm width or less. When the adhering strength is 1 N/10 mm width or more, the rear surface-protective film 911 can adhere to a semiconductor wafer 4 or a semiconductor element with excellent adhesiveness so that this film 911 can also be prevented from undergoing a partial peeling-up and other inconveniences. When the semiconductor wafer 4 is diced, its chips can also be prevented from being scattered. The adhering strength of the rear surface-protective film 911 to a semiconductor wafer 4 is a value measured, for example, as follows: a pressure-sensitive adhesive tape (trade name: “BT315”, manufactured by Nitto Denko Corporation) is bonded to one surface of the rear surface-protective film 911 to reinforce the rear surface. Thereafter, a semiconductor wafer 4 having a thickness of 0.6 mm is bonded to the front surface of the rear surface-reinforced rear surface-protective film 911, which has a length of 150 mm and a width of 10 mm, by a thermal laminating method at 50° C. in which a roller of 2 kg weight is moved forward and backward one time onto the film. Thereafter, the resultant is allowed to stand still on a hot plate (50° C.) for 2 minutes, and then to stand still at room temperature (at about 23° C.) for 20 minutes. After the standing-still, a peeling tester (trade name: “AUTOGRAPH AGS-J”, manufactured by Shimadzu Corporation) is used to peel off the rear surface-reinforced rear surface-protective film 911 at a temperature of 23° C., a peeling angle of 180° and a tensile rate of 300 mm/minute. The adhering strength of the rear surface-protective film 911 to the semiconductor wafer 4 is a value (unit: N/10 mm width) measured for the peel of the rear surface-protective film 911 and the semiconductor wafer 4 from each other at the interface therebetween at this time.

The thickness of the rear surface-protective film 911 is preferably 2 μm or more, more preferably 4 μm or more, even more preferably 6 μm or more, in particular preferably 10 μm or more. In the meantime, the thickness of the rear surface-protective film 911 is preferably 200 μm or less, more preferably 160 μm or less, even more preferably 100 μm or less, even more preferably 80 μm or less, in particular preferably 50 μm or less.

The rear surface-protective film 911 preferably contains a colorant. The colorant may be, for example, a dye or a pigment, and is in particular preferably a dye.

The dye is preferably a deep color dye. Examples of the deep color dye may include black dyes, blue dyes, and red dyes. Black dyes are particularly preferred. Such colorants may be used singly or in any combination of two or more thereof.

The content of the colorant in the rear surface-protective film 911 is preferably 0.5% by weight or more, more preferably 1% by weight or more, even more preferably 2% by weight or more. The content of the colorant in the rear surface-protective film 911 is preferably 10% by weight or less, more preferably 8% by weight or less, even more preferably 5% by weight or less.

The rear surface-protective film 911 preferably contains a thermoplastic resin.

Examples of the thermoplastic resin include a natural rubber, a butyl rubber, an isoprene rubber, a chloroprene rubber, an ethylene-vinyl acetate copolymer, an ethylene-acrylate copolymer, an ethylene-acrylic ester copolymer, a polybutadiene resin, a polycarbonate resin, a thermoplastic polyimide resin, polyamide resins such as 6-nylon and 6,6-nylon, a phenoxy resin, an acrylic resin, saturated polyester resins such as PET (polyethylene terephthalate) and PBT (polybutylene terephthalate), a polyamideimide resin, and a fluororesin. The thermoplastic resins can be used alone or two types or more can be used together. Among these thermoplastic resins, an acrylic resin and a phenoxy resin are preferable.

The acrylic resin is not especially limited, and examples thereof include a polymer having one type or two types or more of acrylates or methacrylates having a linear or branched alkyl group having 30 or less carbon atoms (preferably 4 to 18 carbon atoms, further preferably 6 to 10 carbon atoms, and especially preferably 8 or 9 carbon atoms) as a component. That is, the acrylic resin of the present invention has a broad meaning and also includes a methacrylic resin. Examples of the alkyl group include a methyl group, an ethyl group, a propyl group, an isopropyl group, an n-butyl group, a t-butyl group, an isobutyl group, a pentyl group, an isopentyl group, a hexyl group, a heptyl group, a 2-ethylhexyl group, an octyl group, an isooctyl group, a nonyl group, an isononyl group, a decyl group, an isodecyl group, an undecyl group, a dodecyl group (a lauryl group), a tridecyl group, a tetradecyl group, a stearyl group, and an octadecyl group.

Other monomers that can form the above-described acrylic resin (monomers other than an alkylester of acrylic acid or methacrylic acid having an alkyl group having 30 or less carbon atoms) are not especially limited. Examples thereof include carboxyl-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth) acrylate, and (4-hydroxymethylcyclohexyl) methylacrylate; monomers which contain a sulfonic acid group, such as styrenesulfonic acid, allylsulfonic acid, 2-(meth)acrylamide-2-methylpropanesulfonic acid, (meth)acrylamidepropane sulfonic acid, sulfopropyl (meth) acrylate, and (meth)acryloyloxynaphthalenesulfonic acid; and monomers which contain a phosphoric acid group, such as 2-hydroxyethylacryloylphosphate. (Meth)acrylate refers to an acrylate and/or a methacrylate, and every “(meth)” in the present invention has the same meaning.

The content of the thermoplastic resin in the rear surface-protective film 911 is preferably 10% by weight or more, more preferably 30% by weight or more. The content of the thermoplastic resin in the rear surface-protective film 911 is preferably 90% by weight or less, more preferably 70% by weight or less.

The rear surface-protective film 911 may contain a thermosetting resin.

Examples of the thermosetting resin include an epoxy resin, a phenolic resin, an amino resin, an unsaturated polyester resin, a polyurethane resin, a silicone resin, and a thermosetting polyimide resin. The thermosetting resins can be used alone or two types or more can be used together. An epoxy resin having a small amount of ionic impurities that erode the semiconductor element is especially suitable as the thermosetting resin. Further, a phenolic resin can be suitably used as a curing agent for the epoxy resin.

The epoxy resin is not especially limited, and examples thereof include bifunctional epoxy resins and polyfunctional epoxy resins such as a bisphenol A type epoxy resin, a bisphenol F type epoxy resin, a bisphenol S type epoxy resin, a brominated bisphenol A type epoxy resin, a hydrogenated bisphenol A type epoxy resin, a bisphenol AF type epoxy resin, a bisphenyl type epoxy resin, a naphthalene type epoxy resin, a fluorene type epoxy resin, a phenol novolak type epoxy resin, an ortho-cresol novolak type epoxy resin, a trishydroxyphenylmethane type epoxy resin, and a tetraphenylolethane type epoxy resin, a hydantoin type epoxy resin, a trisglycidylisocyanurate type epoxy resin, and a glycidylamine type epoxy resin.

Out of these examples, particularly preferred are novolak type epoxy resin, biphenyl type epoxy resin, trishydroxyphenylmethane type epoxy resin, and tetraphenylolethane type epoxy resin. This is because these epoxy resins are rich in reactivity with phenolic resin as the curing agent, and are excellent in heat resistance and the like.

The phenolic resin acts as a curing agent for the epoxy resin, and examples thereof include novolak type phenolic resins such as a phenol novolak resin, a phenol aralkyl resin, a cresol novolak resin, a tert-butylphenol novolak resin, and a nonylphenol novolak resin, a resol type phenolic resin, and polyoxystyrenes such as polyparaoxystyrene. The phenolic resins can be used alone or two types or more can be used together. Among these phenolic resins, a phenol novolak resin and a phenol aralkyl resin are especially preferable because connection reliability in a semiconductor device can be improved.

The phenolic resin is suitably compounded in the epoxy resin so that a hydroxyl group in the phenolic resin to 1 equivalent of an epoxy group in the epoxy resin component becomes 0.5 to 2.0 equivalents. The ratio is more preferably 0.8 to 1.2 equivalents.

The content of the thermosetting resin in the rear surface-protective film 911 is preferably 2% by weight or more, more preferably 5% by weight or more. The content of the thermosetting resin in the rear surface-protective film 911 is preferably 40% by weight or less, more preferably 20% by weight or less.

The rear surface-protective film 911 may contain a thermosetting promoting catalyst for the epoxy resin and the phenolic resin. The thermosetting promoting catalyst is not particularly limited, and may be appropriately selected from known thermosetting promoting catalysts. The thermosetting promoting catalysts may be used singly or in any combination of two or more thereof. The thermosetting promoting catalysts may be, for example, amine type, phosphorus-containing type, imidazole type, boron-containing type, and phosphorus-boron-containing type thermosetting promoting catalysts.

In order to crosslink the rear surface-protective film 911 to some degree in advance, it is preferred in the production of the rear surface-protective film 911 to add the following as a crosslinking agent to the rear surface-protective film 11: a polyfunctional compound reactive with, for example, a functional group of a molecular chain terminal of a polymer. This makes it possible to improve the film 11 in adhesive property at high temperature and heat resistance.

The crosslinking agent is not especially limited, and a known crosslinking agent can be used. Specific examples thereof include an isocyanate crosslinking agent, an epoxy crosslinking agent, a melamine crosslinking agent, a peroxide crosslinking agent, a urea crosslinking agent, a metal alkoxide crosslinking agent, a metal chelate crosslinking agent, a metal salt crosslinking agent, a carbodiimide crosslinking agent, an oxazoline crosslinking agent, an aziridine crosslinking agent, and an amine crosslinking agent. An isocyanate crosslinking agent and an epoxy crosslinking agent are preferable. The crosslinking agents can be used alone or two type or more can be used together.

Examples of the isocyanate crosslinking agent include lower aliphatic polyisocyanates such as 1,2-ethylene diisocyanate, 1,4-butylene isocyanate, and 1,6-hexamethylene diisocyanate; alicyclic polyisocyanates such as cyclopentylene diisocyanate, cyclohexylene diisocyanate, isophorone diisocyanate, hydrogenated tolylene diisocyanate, and hydrogenated xylene diisocyanate; and aromatic polyisocyanates such as 2,4-tolylene diisocyanate, 2,6-tolylene diisocyanate, 4,4′-diphenylmethanediisocyanate, and xylylene diisiocyanate. A trimethylolpropane/tolylene diisocyanate trimer adduct (tradename: Coronate L manufactured by Nippon Polyurethane Industry Co., Ltd.) and a trimethylolpropane/hexamethylene diisocyanate trimer adduct (tradename: Coronate HL manufactured by Nippon Polyurethane Industry Co., Ltd.) can also be used. Examples of the epoxy crosslinking agent include N,N,N′,N′-tetraglycidyl-m-xylenediamine, diglycidylaniline, 1,3-bis(N,N-glycidylaminomethyl)cyclohexane, 1,6-hexanediol diglycidylether, neopentylglycol diglycidylether, ethyleneglycol diglycidylether, propyleneglycol diglycidylether, polyethyleneglycol diglycidylether, polypropyleneglycol diglycidylether, sorbitol polyglycidylether, glycerol polyglycidylether, pentaerythritol polyglycidylether, polyglyserol polyglycidylether, sorbitan polyglycidylether, trimethylolpropane polyglycidylether, diglycidyl adipate, diglycidyl o-phthalate, triglycidyl-tris(2-hydroxyethyl)isocyanurate, resorcin diglycidylether, bisphenol-s-diglycidyl ether, and an epoxy resin having two or more epoxy groups in the molecule.

In the present invention, it is possible to perform a crosslinking treatment by irradiation with an electron beam, an ultraviolet ray, or the like in place of using the crosslinking agent or together with a crosslinking agent.

The rear surface-protective film 911 may contain a filler. When the rear surface-protective film 911 contains the filler, the film 911 can be adjusted in elastic modulus and others.

The filler may be an inorganic filler or an organic filler, and is preferably an inorganic filler. The inorganic filler may be powder of an inorganic substance that may be of various type. Examples of the substance include ceramics such as silica, clay, plaster, calcium carbonate, barium sulfate, alumina, beryllium oxide, silicon carbide and silicon nitride; metals such as aluminum, copper, silver, gold, nickel, chromium, lead, tin, zinc, palladium and solder, and any alloy composed of two or more of these metals; and carbon. Such fillers may be used singly or in any combination of two or more thereof. The filler is preferably silica, in particular preferably fused silica. The average particle diameter of the inorganic filler ranges preferably from 0.1 μm to 80 μm. The average particle diameter of the inorganic filler is measurable, using, for example, a laser diffraction type particle size distribution measuring instrument.

The content of the filler in the rear surface-protective film 911 is preferably 10% by weight or more, more preferably 20% by weight or more. The content of the filler in the rear surface-protective film 911 is preferably 70% by weight or less, more preferably 50% by weight or less.

The rear surface-protective film 911 may appropriately contain any other additive. Examples of the other additive include a flame retardant, a silane coupling agent, an ion trapping agent, an extender, an anti-aging agent, an antioxidant, and a surfactant.

Examples of the flame retardant include antimony trioxide, antimony pentoxide, and a brominated epoxy resin. These can be used alone or two types or more can be used together. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These compounds can be used alone or two types or more can be used together. Examples of the ion trap agent include hydrotalcites and bismuth hydroxide. These can be used alone or two types or more can be used together.

The rear surface-protective film 911 can be yielded by, for example, a method of mixing a thermosetting resin, a thermoplastic resin, a solvent and others with one another to prepare a mixed liquid, applying the mixed liquid onto a peeling paper piece, and drying the resultant workpiece.

### Modified Example 1

The rear surface-protective films 911 each have a multilayered form including a first layer and a second layer disposed on the first layer.

### Examples

Hereinafter, preferred examples of this invention will be demonstratively described in detail. However, materials, blend amounts and others that are described in the examples do not for limiting the gist of the invention to only those unless otherwise specified.

### [Production of Rear Surface-Protective Films]

Components used to produce rear surface-protective films are as follows:

Epoxy resin: “HP-4700”, manufactured by DIC Corporation

Phenolic resin: “MEH-7851H”, manufactured by Meiwa Plastic Industries, Ltd.

Acrylic rubber: “TEISAN RESIN SG-P3”, manufactured by Nagase ChemteX Corp.

Silica filler: “SE-2050-MCV” (average primary particle diameter: 0.5 μm) manufactured by Admatechs Co., Ltd.

Colorant 1: “NUBIAN BLACK TN877”, manufactured by Orient Chemical Industries Co., Ltd.

Colorant 2: “SOM-L-0543”, manufactured by Orient Chemical Industries Co., Ltd.

Colorant 3: “ORIPACS B-35”, manufactured by Orient Chemical Industries Co., Ltd.

In each of the examples, in accordance with blend proportions shown in Table 1, individual components were dissolved into methyl ethyl ketone to prepare a solution of an adhesive composition that had a solid concentration of 22% by weight. The adhesive composition solution was applied onto a peel liner (polyethylene terephthalate film subjected to silicone release treatment and having a thickness of 50 μm). Thereafter, the resultant was dried at 130° C. for 2 minutes to produce each rear surface-protective film. The thickness of the rear surface-protective film is shown in Table 1.

### [Evaluations]

About the rear surface-protective films of the example, evaluations described below were made. The results are shown in Table 1.

### (Total Light Transmittance at Wavelength of 555 nm)

About one of the rear surface-protective films, the total light transmittance (%) at a wavelength of 555 nm was measured under the following conditions:

### <Light Transmittance Measuring Conditions>

Measuring device: ultraviolet-visible near infrared spectrophotometer, V-670DS (manufactured by JASCO Corporation)

Speed: 2000 nm/minute

Measuring range: 400 to 1600 nm

Integrating sphere: ISN-723

Spot diameter: 1 cm square

### (Notch Detection)

One of the rear surface-protective films was bonded to an 8-inch mirror wafer at 70° C. When the notch in the resultant was detectable through a digital microscope at a light intensity of 50%, the rear surface-protective film was judged to be ◯; or when the notch was not detectable, the rear surface-protective film was judged to be x.

### Gel Fraction:

(Gel Fraction)

From one of the rear surface-protective films, about 0.1 g of a fraction was sampled and the fraction was precisely weighed (the weight of the sample). The sample was wrapped with a mesh-form sheet, and then the resultant was immersed in about 50 mL of ethanol at room temperature for one week. Thereafter, a matter insoluble in the solvent (the content in the mesh-form sheet) was taken out from ethanol, and then dried at 130° C. for about 2 hours. The dried matter insoluble in the solvent was weighed (the weight of the sample after the immersion and the drying). The gel fraction (%) in the sample was calculated out in accordance with the following equation (a):

Gel fraction (%)=[“the weight of the sample after the immersion and the drying”/“the weight of the sample”]×100 (a)

### Tensile Storage Elastic Modulus:

(Tensile Storage Elastic Modulus)

A dynamic viscoelasticity measuring device “Solid Analyzer RS A2” manufactured by Rheometric was used to measure, in a tensile mode, a tensile storage elastic modulus with a sample (width: 10 mm, length: 22.5 mm, and thickness: 0.2 mm) at a frequency of 1 Hz, a temperature-raising rate of 10° C./minute, and a predetermined temperature (23° C.) in a nitrogen atmosphere.

TABLE 1
(Rear surface-protective films)

| | | | | | Comparative |
|---|---|---|---|---|---|
| | | Example 1 | Example 2 | Example 3 | Example 1 |
| Blend proportions | Epoxy resin (HP-4700) | 9 | 9 | 9 | 9 |
| (part(s) by weight) | Phenolic resin (MEH-7851H) | 12 | 12 | 12 | 12 |
| | Acrylic rubber (SG-P3) | 100 | 100 | 100 | 100 |
| | Silica filler (SE-2050-MCV) | 69 | 69 | 69 | 69 |
| | Colorant 1 (NUBIAN BLACK TN877) | 7 | — | — | — |
| | Colorant 2 (SOM-L-0543) | — | 7 | — | — |
| | Colorant 3 (ORIPACS B-35) | — | — | 7 | 7 |
| Thickness (μm) | | 25 | 25 | 25 | 80 |
| Evaluations | Total light transmittance (% T) at | 5 | 10 | 3 | 1 |
| | 555-nm wavelength | | | | |
| | Notch detection | ◯ | ◯ | ◯ | X |
| | Gel fraction (%) according to | 98 | 97 | 98 | 98 |
| | ethanol extraction | | | | |
| | Tensile storage elastic modulus | 1.7 | 1.5 | 1.9 | 1.9 |
| | (GPa) | | | | |

What is claimed is:

1. A rear surface-protective film for being bonded to a rear surface of a semiconductor wafer,
wherein the rear surface-protective film is smaller in outer circumstance than the semiconductor wafer,
wherein a notch is provided in the rear surface-protective film.

2. A film, comprising:
a separator; and
the rear surface-protective film according to claim 1 disposed on the separator.

3. The film according to claim 2,
wherein the film is in a roll form.

4. A method for producing a semiconductor device, the method comprising:
a step of bonding a semiconductor wafer and a rear surface-protective film to each other,
wherein the rear surface-protective film is smaller in outer circumstance than the semiconductor wafer,
wherein a notch is provided in the rear surface-protective film.

5. The method for producing a semiconductor device according to claim 4,
wherein the step of bonding the semiconductor wafer and the rear surface-protective film to each other is a step of bonding the semiconductor wafer and the rear surface-protective film to each other to form a stacked plate comprising the semiconductor wafer and the rear surface-protective film contacting a rear surface of the semiconductor wafer, the stacked plate being a plate in which the notch in the rear surface-protective film has a contour overlapping with a part of the contour of a notch provided in the semiconductor wafer when the rear surface-protective film is disposed before the semiconductor wafer and the stacked plate is viewed in a direction perpendicular to the semiconductor wafer.

6. The method for producing a semiconductor device according to claim 4,
wherein the step of bonding the semiconductor wafer and the rear surface-protective film to each other is a step of bonding the semiconductor wafer and the rear surface-protective film to each other to form a stacked plate comprising the semiconductor wafer and the rear surface-protective film contacting a rear surface of the semiconductor wafer, the stacked plate having such a shape that a notch provided in the semiconductor wafer has a contour positioned outside the contour of the notch in the rear surface-protective film in the radius direction of the semiconductor wafer when the rear surface-protective film is disposed before the semiconductor wafer and the stacked plate is viewed in a direction perpendicular to the semiconductor wafer.

7. A method for producing a chip, the method comprising:
a step of bonding a semiconductor wafer and a rear surface-protective film to each other,
wherein the rear surface-protective film is smaller in outer circumstance than the semiconductor wafer,
wherein a notch is provided in the rear surface-protective film.

8. A rear surface-protective film for being bonded to a rear surface of a semiconductor wafer,
wherein the rear surface-protective film has a total light transmittance of 3% or more at a wavelength of 555 nm.

9. A film, comprising:
a separator; and
the rear surface-protective film according to claim 8 disposed on the separator.

10. A method for producing a semiconductor device, the method comprising:
a step of bonding the semiconductor wafer and the rear surface-protective film to according to claim 8 each other.

11. A method for producing a chip, the method comprising:
a step of bonding a semiconductor wafer and the rear surface-protective film according to claim 8 to each other.
